(19) United States
(12) Patent Application Publication
(10) Pub. No.: US 2026/0353587 A1
(43) Pub. Date: Nov. 5, 2026

(54) FIBER DISTRIBUTION SYSTEMS AND COMPONENTS THEREOF

(71) Applicant: Amphenol Network Solutions, Inc., Liberty Lake, WA (US)

(72) Inventors: Timothy McBrien Turpin, Liberty Lake, WA (US); Harley McAllister, Liberty Lake, WA (US); Greg Hilbert, Liberty Lake, WA (US)

(21) Appl. No.: 19/663,171

(22) Filed: Apr. 29, 2026

Related U.S. Application Data
(60) Provisional application No. 63/797,721, filed on Apr. 30, 2025.

(51) Int. Cl. H05K 7/14; G02B 6/44; H05K 5/02

(52) U.S. Cl. CPC H05K 7/1487; G02B 6/444; H05K 5/0247; H05K 7/1491

(57) ABSTRACT

A data communication apparatus includes a chassis. The chassis includes a first sidewall extending from a rear wall, and a second sidewall extending from the rear wall. A gate fixed to the first or second sidewall. The gate including a channel configured to receive fiber optic cable therethrough, an attachment mechanism disposed at a first end of the channel for attaching the gate to the first sidewall or the second sidewall, and a flap attached to a second end of the channel. The flap being attached to the second end of the channel via a living hinge such that the flap is displaceable between an open position and a closed position. When in the closed position the flap is positioned to enclose the channel and when in the open position the flap is positioned to permit access to an interior of the channel.

### CROSS REFERENCE TO RELATED APPLICATION

This application claims priority to U.S. Provisional Application No. 63/797,721, filed Apr. 30, 2025, titled Fiber Distribution Systems and Components Thereof, the entirety of which is incorporated herein by reference.

### BACKGROUND

An important consideration in data communication equipment is circuit density. Most central data communication locations have limited space. Therefore, there is a need to reduce the size of data communication equipment and install as much data communication equipment as possible in a relatively small space at a central data communication location.

For data communication manufacturers, making high-density data communication apparatuses can be a challenging process in which engineers develop apparatuses to meet the high-density needs of the central data communication locations while protecting communication lines, maintaining bend radii of the communication lines, and managing massive amounts of communication lines. This is particularly true for optical fiber communication lines, where the engineers create apparatuses having a high-density of optical fibers.

### BRIEF DESCRIPTION OF THE DRAWINGS

The embodiments herein may be better understood by referring to the following description:

FIG. 1 illustrates an example data communication apparatus for storing fiber optic cables, preventing damage to the fiber optic cables, and/or ensuring excess amounts of the fiber optic cables are readily accessible for maintenance and/or future use in a telecommunication facility according to an embodiment in this disclosure.

FIG. 2A illustrates a perspective view of a data communication apparatus without a lid to show one or more spool assemblies, and one or more gates of the data communication apparatus according to an embodiment in this disclosure.

FIG. 2B illustrates a perspective view of the data communication apparatus with a shelf in an open position and the one or more gates of FIG. 2A in a closed position according to an embodiment in this disclosure.

FIG. 2C illustrates a perspective view of the data communication apparatus with the shelf of FIG. 2B in the open position and the one or more gates of FIG. 2A in an open position according to an embodiment in this disclosure.

FIG. 3 illustrates an exploded assembly view of a spool assembly as seen on the data communication apparatus in FIGS. 2A, 2B, and 2C, according to an embodiment in this disclosure.

FIG. 4 illustrates a side view of a base portion of the spool assembly shown in FIG. 3 and a top perspective view of a chassis according to an embodiment in this disclosure.

FIG. 5A illustrates a top, perspective view of an embodiment of a gate with a flap in an open position according to an embodiment in this disclosure.

FIG. 5B illustrates a bottom, perspective view of the gate of FIG. 5 with the flap of FIG. 5 in a closed position according to an embodiment in this disclosure.

### DETAILED DESCRIPTION

The detailed description is set forth with reference to the accompanying figures. In the figures, the left-most digit(s) of a reference number identifies the figure in which the reference number first appears. The use of the same reference numbers in different figures indicates similar or identical items. Further, for the sake of clarity, unless otherwise defined hereinafter, the following words, if/when used in this disclosure, are intended to refer to portions, areas, regions, and/or directionalities of the device/features, as understood conventionally and according to the plain meaning of the words, with respect to the device/features described hereinafter, assuming the device/features are being considered in accordance with the presented orientation in the drawings and/or intended use: up, upward, above, down, downward, below, left, right, side, bottom, top, front, back, laterally, beneath, horizontally, vertically, lower, upper, outer, inner, etc. and other like terms. Moreover, such terms are included for the sake of clarity in describing the recited features as depicted in the orientations presented in the drawings.

This disclosure is directed to fiber routing spool assemblies with articulating step flanges for retaining and controlling fiber optic cables about their routing paths in a data communication apparatus. Moreover, this disclosure is further directed to gates for receiving and controlling fiber optic cables entering and/or exiting a data communication apparatus.

In an example situation of use of the fiber routing spool assemblies, telecommunication cables (e.g., fiber optic cable, electrical cable, and/or hybrid cable that includes both electrical and optical conductors) may be cross-connected between multiple data communication apparatuses within a data communication facility (e.g., a datacenter, a cable plant, a headend, a distribution hub, a colocation data center, etc.). When cross-connecting fiber optic cables, an excess length of a fiber optic cable may be routed, coiled, secured, etc., in a shelf (e.g., bulk fiber storage tray) of a chassis for future repairs and/or relocations. For example, depending on a specific cable type, installation environment, and/or application requirements, a user may store an excess amount of slack of fiber optic cable in a shelf for future repairs and/or relocations. Some examples of potential advantages associated with the fiber routing spool assemblies include: easily configurable, facilitating access to the fiber optic cables, and quick storage for amounts of extra fiber optic cables, thereby reducing the need to obtain additional fiber optic cables (e.g., fewer order requests), minimizing labor efforts, and reducing inventory management concerns.

In an example situation of use of the gate, when telecommunication cables are routed into and/or out of the chassis, the telecommunication cables may be routed in through a first gate disposed in a first wall of a first side of the chassis and out through a second gate disposed in a second wall of the chassis. For example, depending on a specific cable type, installation environment, and/or application requirements, a user may route fiber optic cables in through the first gate and out through the second gate to ensure a minimum bend diameter of the fiber optic cables is maintained at the first and second gates, and keep at least the portions of the fiber optic cables passing through the first and second gates from being displaced, manipulated, kinked, twisted, etc. when opening and/or closing the chassis. Some examples of potential advantages associated with the gates include facilitating access to the fiber optic cables without having to remove the top of the chassis and/or facilitating access to the fiber optic cables without having to remove a second chassis directly above the chassis, thereby minimizing labor efforts and reducing costs.

While this application describes implementations that are described in the context of data communication apparatuses for bulk optical fiber storage in a telecommunications facility, the implementations described herein may be used in other environments and are applicable to other contexts. For example, the data communication apparatuses may be located at any desired location, including overhead, below the floor, indoor or outdoor, at a workstation, at a desk, in a home, in an office, in an underground or above ground enclosure (including, e.g., pole-mounted or other areal enclosures), in a home theater, for use with a personal computer, with a personal workstation, with an audio system, in a vehicle, in a boat, etc. In addition, the data communication apparatuses may be used to connect a variety of elongated members other than optical fibers, such as wires, Ethernet cables, coaxial cables, power cords, wiring harnesses, etc.

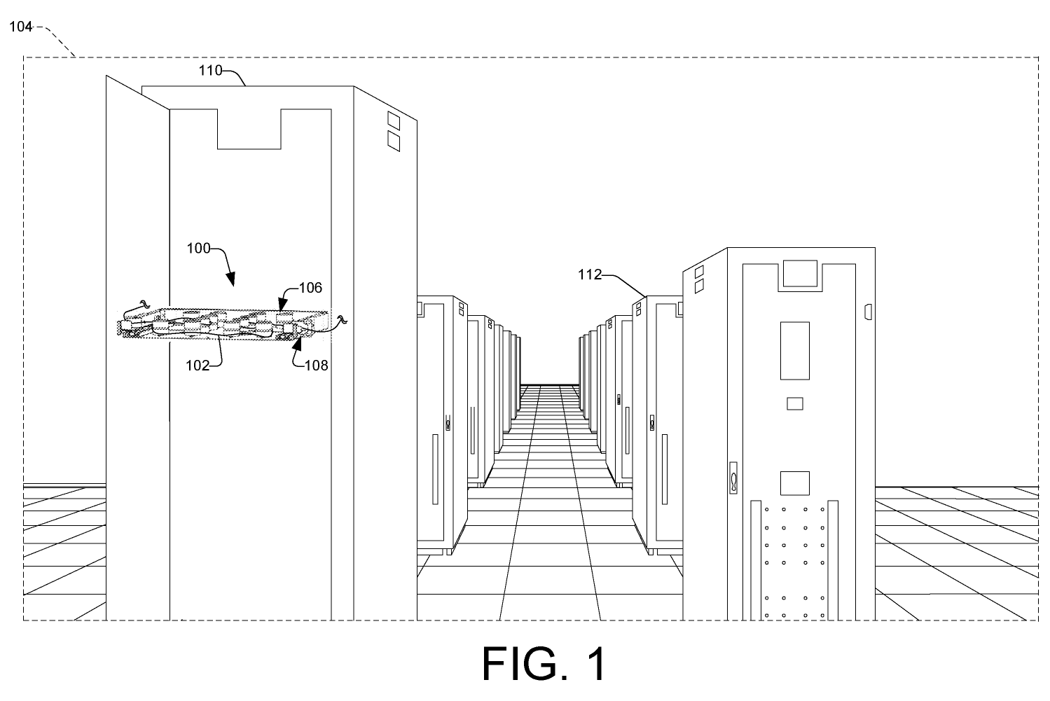

FIG. 1 illustrates an example data communication apparatus 100 for storing fiber optic cables 102, preventing damage to the fiber optic cables 102, and/or ensuring excess amounts of the fiber optic cables 102 are readily accessible for maintenance and/or future use in a telecommunication facility 104. The data communication apparatus 100 may include one or more spool assemblies, such as spool assemblies 106, and/or one or more gates, such as gates 108. FIG. 1 illustrates the data communication apparatus 100 without a lid and without a front panel to clearly show the one or more spool assemblies 106 and the gates 108 of the data communication apparatus 100. The one or more spool assemblies 106 within the data communication apparatus 100 may include one or more displaceable flanges, which greatly facilitate accessing the fiber optic cables 102 during and after installation. The gates 108 may include a front-facing flap that opens to make it easier to get fibers into and out of the tray without having to remove the lid (not shown) of the data communication apparatus or without having to remove another data communication apparatus (not shown) disposed on top of the data communication apparatus 100. The gates 108 may be several times larger than those in legacy slack storage trays, providing a quantity of about 96 fiber optic cable capacity, where each of the 96 fiber optic cables may have a diameter of about 1.6 mm. A user (e.g., a technician) may install the data communication apparatus 100 in the telecommunication facility 104 for storing excess amounts of fiber optic cables cross-connecting in the telecommunication facility 104. For example, a user may install the data communication apparatus 100 in a first cabinet 110 for storing excess amounts of fiber optic cables cross-connecting to a second cabinet 112 for telecommunication equipment located a distance away from the first cabinet 110. For example, the fiber optic cables 102 stored in the data communication apparatus 100 in the first cabinet 110 may be routed to the second cabinet 112, or any other cabinet.

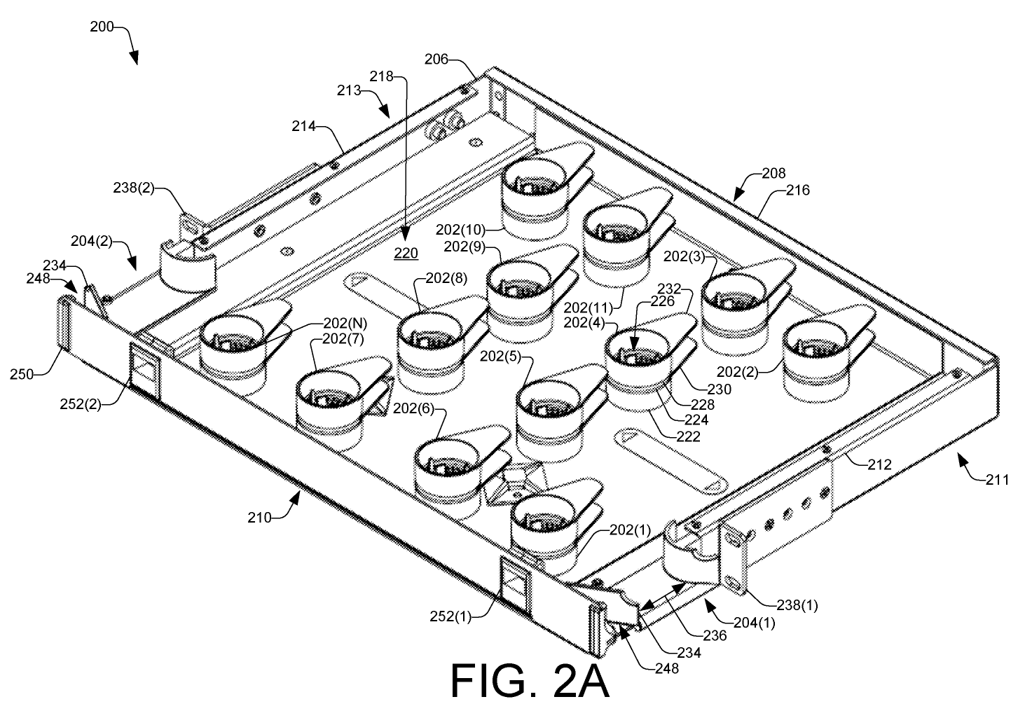

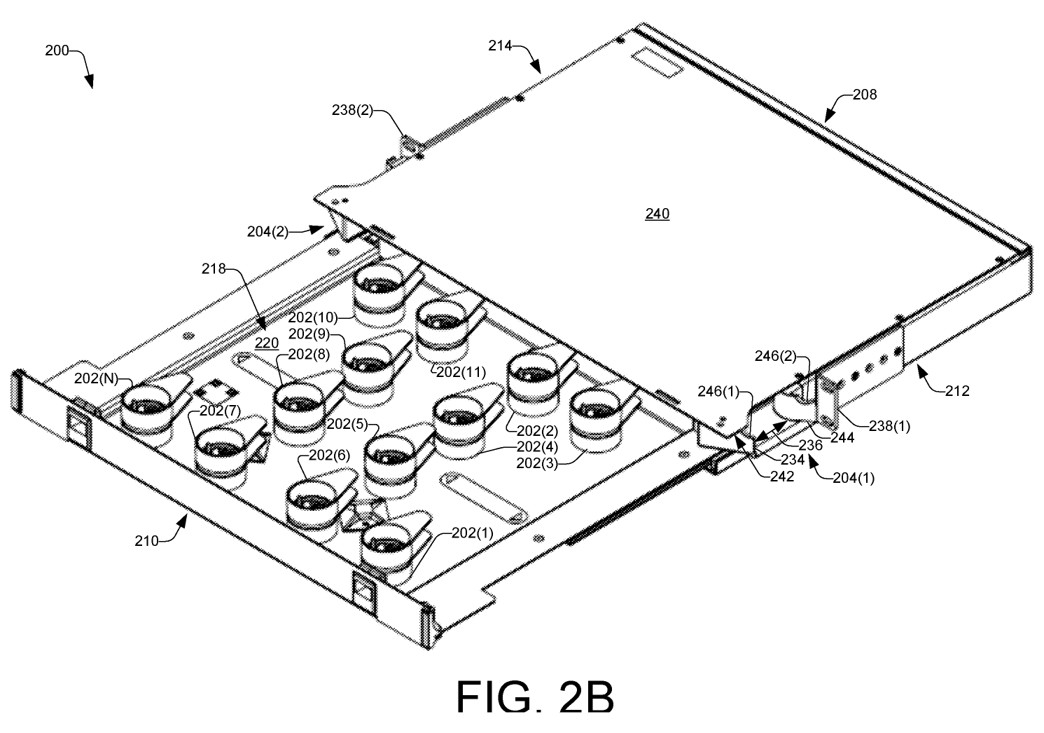

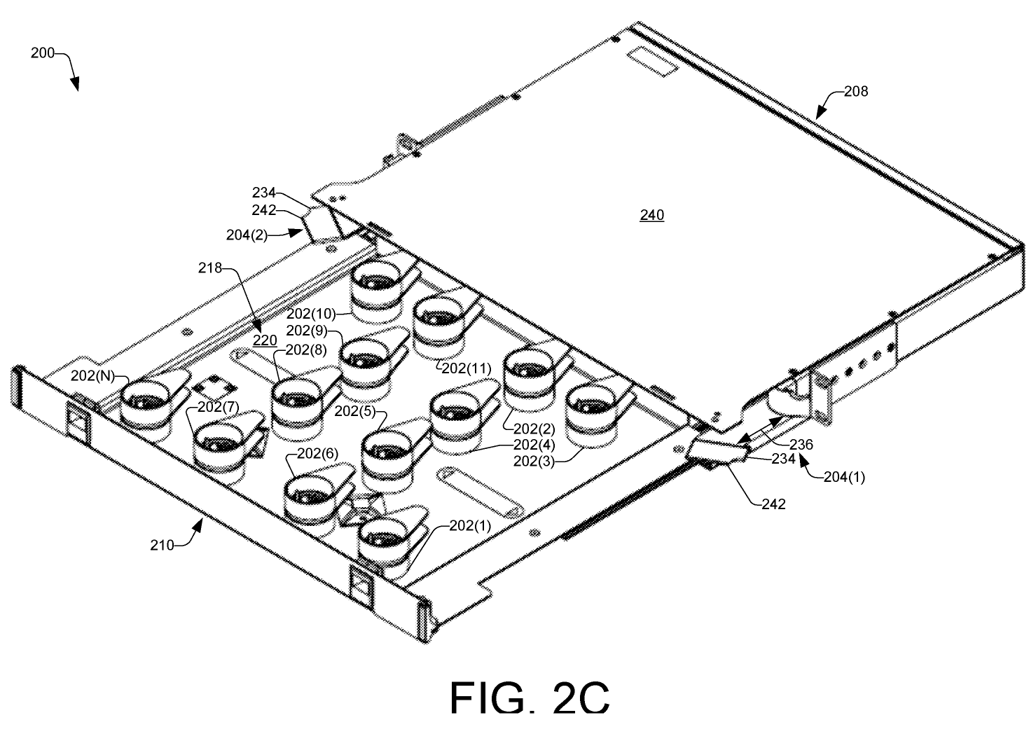

FIG. 2A illustrates the data communication apparatus 200 without a lid to show one or more spool assemblies 202(1), 202(2), 202(3), 202(4), 202(5), 202(6), 202(7), 202(8), 202(9), 202(10), 202(11) and 202(N), and one or more gates 204(1) and 204(2) of the data communication apparatus 200 (where “N” is a number greater than 1). The data communication apparatus 200 may be the same as the data communication apparatus 100 shown in FIG. 1. The one or more spool assemblies 202(1)-202(N) may be the same as the one or more spool assemblies 106 shown in FIG. 1. The one or more gates 204(1) and 204(2) may be the same as the gates 108 shown in FIG. 1.

The data communication apparatus 200 may include a chassis 206. The chassis 206 may be a bulk fiber storage tray configured to support the one or more spool assemblies 202(1)-202(N), the one or more gates 204(1) and 204(2), and massive amounts of the fiber optic cables (e.g., fiber optic cables 102) (about 96 fiber optic cables having a diameter of about 1.6 mm), for example. In an embodiment, the chassis 206 may be defined, at least in part, by a rear side 208 (i.e., the location which may be referred to by some in the industry as the “back bulkhead” side) opposite a front access side 210, and a first side 211 opposite a second side 213. The chassis 206 may include a rear wall 216 disposed at the rear side 208. A first sidewall 212 may extend from the rear wall 216 at the rear side 208 toward the front access side 210 proximate to the first side 211, and a second sidewall 214 may extend from the rear wall 216 at the rear side 208 toward the front access side 210 proximate to the second side 213. A shelf 218 having a surface 220 may extend from the rear wall 216 at the rear side 208 to the front access side 210. As shown, the surface 220 may be substantially planar. The surface 220 facilitates attaching the one or more spool assemblies 202(1)-202(N) to the surface 220 of the shelf 218 to be supported thereon.

The shelf 218 may be displaceable between a stowed position and an open position. FIG. 2A illustrates the shelf 218 in the stowed position. When in the stowed position, the shelf 218 may be disposed inside the chassis 206 and covered by a lid (shown in FIGS. 2B and 2C). Correspondingly, when in the open position, the shelf 218 may be disposed outside of the chassis 206 and not covered by the lid. Thus, the shelf 218 may either be disposed inside the chassis 206 and enclosed by the chassis 206 protecting the one or more spool assemblies 202(1)-202(N) and the fiber optic cables managed by the spool assemblies 202(1)-202(N), or the shelf 218 may be pulled outward and uncovered to permit access to the interior thereof.

Though many spool assemblies 202(1)-202(N) are depicted, for the sake of clarity, the following discussion will describe the attributes of a single spool assembly (depicted near the center of FIG. 2A, and referred to herein simply as spool assembly SA, but not labeled as SA in the figures), which attributes equally apply to any and/or all of the one or more spool assemblies 202(1)-202(N).

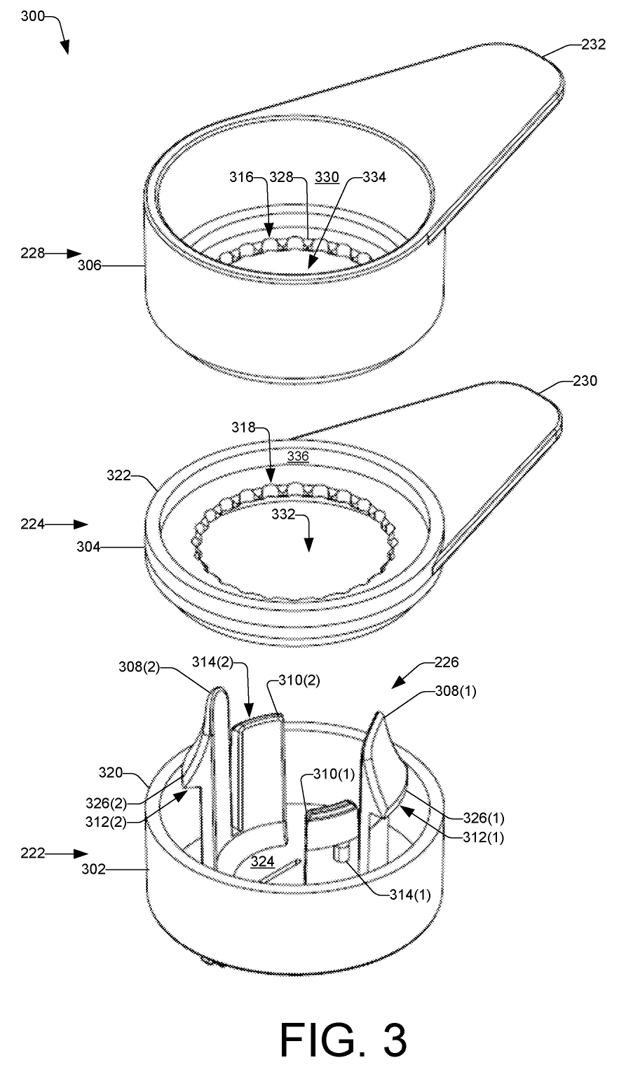

Accordingly, a spool assembly SA may include a base portion 222 removably attachable to the surface 220 of the shelf 218. In an embodiment, the spool assembly SA may include a middle portion 224 rotatably attached to the base portion 222 via an interlocking structure 226. As used herein, the term "interlocking structure" may refer to a central structural assembly disposed within an interior region of a base portion of the spool assembly and surrounded by a first cylindrical wall of the base portion. The interlocking structure may define a longitudinal rotational interlocking structure extending generally perpendicular to the surface of the shelf (the interlocking structure is described in detail below with respect to FIG. 3). Further, the spool assembly SA may include a top portion 228 rotatably attached to the middle portion 224 via the interlocking structure 226. In an embodiment, the spool assembly SA may include a first flange 230 extending laterally from the middle portion 224. Further, the spool assembly SA may include a second flange 232 extending laterally from the top portion 228.

The first flange 230 may be rotatable via the rotatably attached middle portion 224, and the second flange 232 may be rotatable via the rotatably attached top portion 228. The first flange 230 may be rotated clockwise or counterclockwise about the interlocking structure 226, independently of the second flange 232. Similarly, the second flange 232 may be rotated clockwise or counterclockwise about the interlocking structure 226, independently of the first flange 230. As such, rotating first flange 230 and rotating the second flange 232 facilitate accessing the fiber optic cables during and after installation of the fiber optic cables. For example, a user may rotate the first flange 230 to route fiber optic cables around the base portion 222 of the spool assembly 202(4) and/or rotate the second flange 232 to route fiber optic cables around the top portion 228. In this way, a user may rotate the first flanges and/or the second flanges of the spool assembly SA to facilitate accessing the fiber optic cables routed around the top portions and/or the bottom portions of the spool assembly SA during and after installation of the fiber optic cables.

Notably, the fiber optic cables may be sized in length to any desirable length depending on a size of the outside diameter of the fiber optic cables, which may vary. That is, the fixed size (including outer diameter and height, as well as the diameter of the top portion and/or the bottom portion of the spool assembly around which fiber optic cables may be wound) of a spool assembly SA may accommodate a range of lengths of fiber optic cables depending on the diameter of the fiber optic cables. Thus, a smaller diameter fiber optic cable permits additional length, while a larger diameter fiber optic cable will reduce the amount of length the same spool assembly SA could accommodate. For example, in an embodiment, the spool assembly SA (as contemplated for implementation in the circumstances associated with the instant disclosure) carrying a full load of cable may be sized to accommodate a range of cable length of 2ft to 6ft, depending on the diameter of the cable which may range from 1.6 mm to 3 mm. Alternatively, a fiber optic cable having a diameter measured in microns (e.g., 50 microns-100 microns) may permit a spool assembly to carry a length of cable that is greater than 6ft; and a fiber optic cable having a diameter measured in mm (e.g., 1mm-5mm or larger) may permit a spool assembly to carry a length of cable that is less than 6ft. Nevertheless, the amount to be stored depends on at least the size of the spool assembly SA and the diameter of the selected fiber optic cable, as well as user and business preferences, economics, needs, etc.

Though two gates 204(1) and 204(2) are depicted, for the sake of clarity, the following discussion will describe the attributes of a single gate 204(1) (depicted at the right side front corner of the chassis in FIGS. 2A-2C), which attributes equally apply to both gates 204(1) and 204(2). Gate 204(1) may include a flap 234 attached to chassis 206 so as to form one side of a channel 236 configured to receive fiber optic cable therethrough. That is, in a first position (FIG. 2B), the flap 234 may be folded upward, hingedly connected to the surface 220 of the chassis 206—such as via a living hinge—to secure in position and/or protect any fiber optic cables within the channel 236 of the gate 204(1). In a second position (FIG. 2C), the flap 234 may be folded downward against a portion of the surface 220, thereby facilitating easier user access to any fiber optic cables within the channel 236.

FIGS. 2A, 2B, and 2C illustrate that gate 204(1) may be attached proximate to an end of the first sidewall 212, thus opening to the right of the chassis 206, whereas the gate 204(2) may be attached proximate to an end of the second sidewall 214, and open to the left of the chassis 206.

In an embodiment, the chassis 206 may further include brackets 238(1) and 238(2) disposed, respectively, on an outer surface of the first sidewall 212 and the second sidewall 214 of the front access side 210. In an embodiment, the brackets 238(1), 238(2) may be L-shaped to pair a portion with the first and second sidewalls 212, 214, while the other portion of the L-shape extends outwardly to connect to a rack. Thus, the brackets 238(1), 238(2) are positioned to mount the chassis 206 to a rack (not shown), such as a 19-inch rack, which is a standard size rack in the industry. Moreover, inasmuch as the chassis 206 may be installed in racks which may not be exactly the same across the industry, the brackets 238(1) and 238(2) may be configured according to the particular circumstances. For example, the brackets 238(1) and 238(2) may have one or more structural features, such as holes, slots, protrusions, etc., that pair with corresponding features of the particular rack to which the chassis 206 is installed. Likewise, in an embodiment, the one or more structural features on the brackets 238(1), 238(2) may facilitate connection to a plurality of different racks with correspondingly engaging features.

While both FIGS. 2B and 2C illustrate the shelf 218 in the open position, FIG. 2B illustrates the gate 204(1) in a closed position, and FIG. 2C illustrates the gate 204(1) in an open position. As indicated above, when the shelf 218 is in the open position, the lid 240 does not cover the chassis 206, so that the one or more spool assemblies 202(1)-202(N) and the fiber optic cables managed by the spool assemblies 202(1)-202(N) are easily accessible. As such, the shelf 218 may be disposed on rails and slideably displaced between the stowed position and the open position.

Thus, user access to any fiber optic cables within the channel 236 is attainable without removing the lid 240, or without removing another chassis if one is disposed directly above the chassis 206, when installed in a rack, for example.

The gates 204(1) and 204(2) may include a bumper 244, respectively, for protecting the fiber optic cable received through the channel 236. In an embodiment, the flap 234 may include a first notch 246(1) disposed in a top portion thereof, and a second notch 246(2) may be disposed in a top portion of the bumper 244. The first notch 246(1) and second notch 246(2) may be sized/shaped to permit a tool access to mount the chassis 206 with hardware. For example, when installing the data communication apparatus 200 in a cabinet (e.g., first cabinet 110), a user (e.g., technician) may pass a long shaft screwdriver through the first notch 246(1) and/or the second notch 246(2) to tighten one or more fasteners disposed in openings of the brackets 238(1) and 238(2) to mount the chassis 206 to a rack of the cabinet.

Subsequent to mounting the chassis 206 to a rack of a cabinet, the user may add optical fiber to the chassis 206. For example, after mounting the chassis 206 to a rack, the user may displace the chassis 206 from the stowed position to the open position, displace gate 204(2), for example, from the closed position to the open position, and begin adding optical fiber to the chassis 206 via the open gate 204(2) and the accessible spool assemblies 202(1)-202(N) in the open chassis 206. For example, the fiber optic cable may be wrapped around the spool assemblies 202(9) and 202(8), which in the instant case are the most centrally located within the chassis. In an embodiment, the user may begin wrapping the fiber optic cable around any of the spool assemblies, whether located centrally or otherwise, but in an alternative embodiment, the user may start in the spool assemblies near or at the center of the chassis 206. In the example where the user starts wrapping the cable in the centermost spool assemblies, the user may continue to route the fiber optic cable around as many of the other spool assemblies as is needed to take up the slack in the cable. If the user is routing fiber optic cable on both a first level (i.e., first level may be defined by the base portions 222 of each of the one or more spool assemblies 202(1)-202(N)) and a second level (i.e., second level may be defined by top portions 228 of each of the one or more spool assemblies 202(1)-202(N)) of the chassis 206, the user may route the fiber optic cable on the outside of the one or more spool assemblies 202(1)-202(N)) so that the fiber optic cables do not cross over themselves.

After routing the fiber optic cables around the spool assemblies 202(1)-202(N)), the user may route the fiber optic cables out through channel 236(1) of the opposing gate 204(1). The user may proceed to displace the respective flaps 234 of the gates 204(1) and 204(2) into the closed position, thereby enclosing the channels 236, holding, and/or protecting the fiber optic cables routed within the channels 236 of the gates 204(1) and 204(2). The user may then displace the shelf 218 from the open position to the closed position, such that the shelf 218 is disposed inside the chassis 206 and covered by the lid 240. The closed gate 204(1) may prevent the portions of the fiber optic cables disposed in the channel 236 of the gate 204(1) from being displaced when displacing the shelf 218 between the open position and the closed position. Moreover, as shown in FIG. 2A, the closed gate 204(1) may provide a gap 248 between a front panel 250 of the shelf 218 and the flap 234 of the closed gate 204(1). The gap 248 may provide for a fingertip to pull the shelf 218 and displace the shelf 218 from the stowed position to the open position. For example, a user may actuate one or more latches 252(1) and 252(2) disposed on the front panel of the shelf 218 with a thumb while an index finger pulls on the side of the front panel 250 just behind the flap 234 to displace the shelf 218 from the stowed position to the open position.

Inasmuch as FIG. 3 depicts different elements and features of the one or more spool assemblies, while referring to the same elements and features of the spool assembly 106 and/or the one or more spool assemblies 202(1)-202(N), the following discussion of specific features may refer interchangeably to either or each of FIGS. 1, 2A, 2B, and 2C, except where explicitly indicated. In particular, FIG. 3 illustrates an embodiment of an exploded assembly view of a spool assembly 300, including a first cylindrical wall 302, a second cylindrical wall 304, a third cylindrical wall 306, one or more latching members 308(1) and 308(2), one or more retention members 310(1) and 310(2), one or more retention mechanisms 312(1) and 312(2), one or more retention mechanisms 314(1) and 314(2), one or more cooperating retention mechanisms 316, and one or more cooperating retention mechanisms 318.

FIG. 3 illustrates the interlocking structure 226 surrounded by the first cylindrical wall 302 of the base portion 222. The first cylindrical wall 302 of the base portion 222 having a top surface 320 disposed on a perimeter of the first cylindrical wall 302. The middle portion 224 may be rotatably attached to the base portion 222 via the interlocking structure 226 and the top surface 320 of the first cylindrical wall 302. The middle portion 224 may include the second cylindrical wall 304 having a top surface 322 disposed on a perimeter of the second cylindrical wall 304. FIG. 3 illustrates the first flange 230 extending laterally from the second cylindrical wall 304 of the middle portion 224. The top portion 228 may be rotatably attached to the middle portion 224 via the interlocking structure 226 and the top surface 322 of the second cylindrical wall 304 of the middle portion 224. The top portion 228 may include the third cylindrical wall 306 and the second flange 232 extending laterally from the third cylindrical wall 306 of the top portion 228. In some embodiments, a first plurality of fiber optic cables may be wound around the first cylindrical wall 302 to provide strain relief for the first plurality of fiber optic cables. In some embodiments, a second plurality of fiber optic cables may be wound around the third cylindrical wall 306 to provide strain relief for the second plurality of fiber optic cables. The first flange 230 may be rotatably displaceable about the interlocking structure 226 to provide access to the first plurality of fiber optic cables wound around the first cylindrical wall 302. The second flange 232 may be rotatably displaceable about the interlocking structure 226 to provide access to the second plurality of fiber optic cables wound around the third cylindrical wall 306.

As used herein, the term "interlocking structure" may refer to a central structural assembly surrounded by the first cylindrical wall 302 of the base portion 222, about which the middle portion 224 and the top portion 228 are rotatably attached. The interlocking structure 226 may define a longitudinal rotational interlocking structure extending generally perpendicular to a mounting surface of the base portion 222. The interlocking structure may function as a pivot shaft or spindle assembly that permits coaxial rotational movement of the middle portion 224 and the top portion 228 relative to the base portion 222. In an embodiment, the interlocking structure 226 may include the one or more latching members 308(1) and 308(2) extending from an inside surface 324 of the base portion 222 toward the top surface 320 of the first cylindrical wall 302 of the base portion 222. The one or more latching members 308(1) and 308(2) may include one or more latching mechanisms 326(1) and 326(2) defining outwardly-directed hooks disposed proximate to a top end of the one or more latching members 308(1) and 308(2) for rotatably securing the base portion 222 to a cooperating latching member 328 of the top portion 228. The cooperating latching member 328 at least partially disposed on an inside surface 330 of the third cylindrical wall 306 of the top portion 228. The cooperating latching member 328 may be a substantially planar surface at least partially disposed on an inside surface 330 of the third cylindrical wall 306 of the top portion 228 on which the one or more latching mechanisms 326(1) and 326(2) may be disposed for rotatably securing the base portion 222 to the top portion 228. The one or more latching members 308(1) and 308(2) may further include the one or more retention mechanisms 312(1) and 312(2) disposed proximate to the top ends of the one or more latching members 308(1) and 308(2). For example, the one or more latching members 308(1) and 308(2) may further include the one or more retention mechanisms 312(1) and 312(2) disposed below the one or more latching mechanisms 326(1) and 326(2) disposed proximate to the top end of the one or more latching members 308(1) and 308(2). The one or more retention mechanisms 312(1) and 312(2) may be configured to releasably prevent rotation of the second flange 232 via the one or more cooperating retention mechanisms 316 at least partially disposed on the inside surface 330 of the third cylindrical wall 306 of the top portion 228. The one or more retention mechanisms 312(1) and 312(2) may include raised portions, protrusions, bumps, detent mechanisms, protruding flaps, ball and spring mechanisms, ridges, magnetic connections, etc., configured to cooperate with one or more pockets, openings, grooves, magnetic connections, etc. of the one or more cooperating retention mechanisms 316. While FIG. 3 illustrates the one or more retention mechanisms 312(1) and 312(2) disposed below the one or more latching mechanisms 326(1) and 326(2) and the one or more cooperating retention mechanisms 316, other configurations are contemplated. For example, the one or more retention mechanisms 312(1) and 312(2) may be disposed in the hook end portions of the one or more latching mechanisms 326(1) and 326(2), and the one or more cooperating retention mechanisms 316 may be disposed in a top portion a planar surface disposed on an inside surface of the second cylindrical wall 304 of the middle portion 224.

In an embodiment, as depicted, the one or more latching members 308(1) and 308(2) may include a spring-hinge protrusion with the one or more latching mechanisms 326(1) and 326(2) hooked outwardly, where the protrusion is hingeably connected to the inside surface 324 of the base portion 222. Thus, when the middle portion 224 and/or the top portion 228 are placed on top of the base portion 222, the one or more latching members 308(1) and 308(2) may flap or hinge inwardly toward a center of the interlocking structure 226 of the base portion 222 and pass easily through an aperture 332 of the middle portion 224 and/or an aperture 334 of the top portion 228, for example. Once through the apertures 332 and/or 334, the one or more latching mechanisms 326(1) and 326(2) spring resiliently outward away from the center of the interlocking structure 226 of the base portion 222 rotatably securing the top portion 228 and/or the middle portion 224 to the base portion 222. For example, once through the aperture 332 of the middle portion 224 and then subsequently through the aperture 334 of the top portion 228, the one or more latching mechanisms 326(1) and 326(2) spring resiliently outward away from the center of the interlocking structure 226 of the base portion 222 and onto the cooperating latching member 328 of the top portion 228, sandwiching the middle portion 224 between the top portion 228 and the base portion 222. Thus, rotatably securing the top portion 228 and the middle portion 224 to the base portion 222 such that the first flange 230 may be rotated clockwise or counterclockwise about the interlocking structure 226 independently of the second flange 232, and the second flange 232 may be rotated clockwise or counterclockwise about the interlocking structure 226 independently of the first flange 230.

In an embodiment, as depicted, the interlocking structure 226 may include the one or more retention members 310(1) and 310(2) extending from the inside surface 324 of the base portion 222 toward the top surface 320 of the first cylindrical wall 302 of the base portion 222. The one or more retention members 310(1) and 310(2) may include the one or more retention mechanisms 314(1) and 314(2) disposed proximate to the top ends of the one or more retention members 310(1) and 310(2). Similar to the one or more retention mechanisms 312(1) and 312(2), the one or more retention mechanisms 314(1) and 314(2) may include raised portions, protrusions, bumps, detent mechanisms, protruding flaps, ball and spring mechanisms, ridges, magnetic connections, etc. configured to cooperate with one or more pockets, openings, grooves, magnetic connections etc. of the one or more cooperating retention mechanisms 318. The one or more retention mechanisms 314(1) and 314(2) may be configured to releasably prevent rotation of the first flange 230 of the middle portion 224 via the one or more cooperating retention mechanisms 318 at least partially disposed on an inside surface 336 of the second cylindrical wall 304 of the middle portion 224.

While FIG. 3 illustrates the top portion 228 and the middle portion 224, each including one flange, the top portion 228 and/or the middle portion 224 may include any number of flanges. For example, the top portion 228 and/or the middle portion 224 may include a second flange that may extend laterally from the cylindrical walls 306, 304 of the top portion 228 and/or the middle portion 224 opposite to, or adjacent to, the least one second flange 232 and/or the first flange 230.

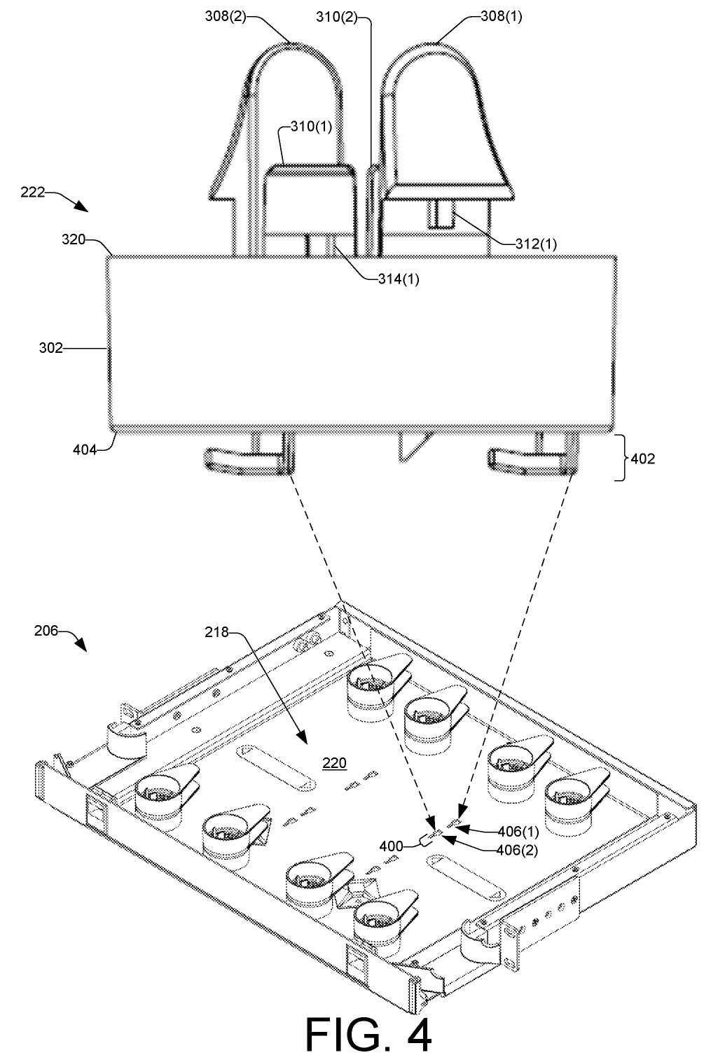

FIG. 4 illustrates a side view of the base portion 222 and a top perspective view of the chassis 206 with the lid 240 and the middle set of spool assemblies 202(4), 202(5), 202(8), and 202(9) not shown to show details of a cooperating locking feature 400 disposed in the surface 220 of the shelf 218 for cooperatively locking with a locking mechanism 402 disposed on a bottom surface 404 of the base portion 222. For example, the base portion 222 may further include the locking mechanism 402 disposed on the bottom surface 404 of the base portion 222 to removably attach the base portion 222 to the cooperating locking feature 400 disposed in the surface 220 of the shelf 218. While FIG. 4 illustrates the locking mechanism 402 including an L-shaped protrusion extending from the bottom surface 404 of the base portion 222 to pair with cooperatively shaped openings 406(1) and 406(2) of the cooperating locking feature 400 disposed in the surface 220 of the shelf 218, other locking mechanisms are contemplated. For example, alternatively, the base portion 222 may connect to the surface 220 of the shelf 218 via other means (and/or at other locations on the surface 220 of the shelf 218), including: magnetic attraction, a snap fit, a compression fit, a hook and catch, a latch mechanism, hook and loop material, adhesive, etc.

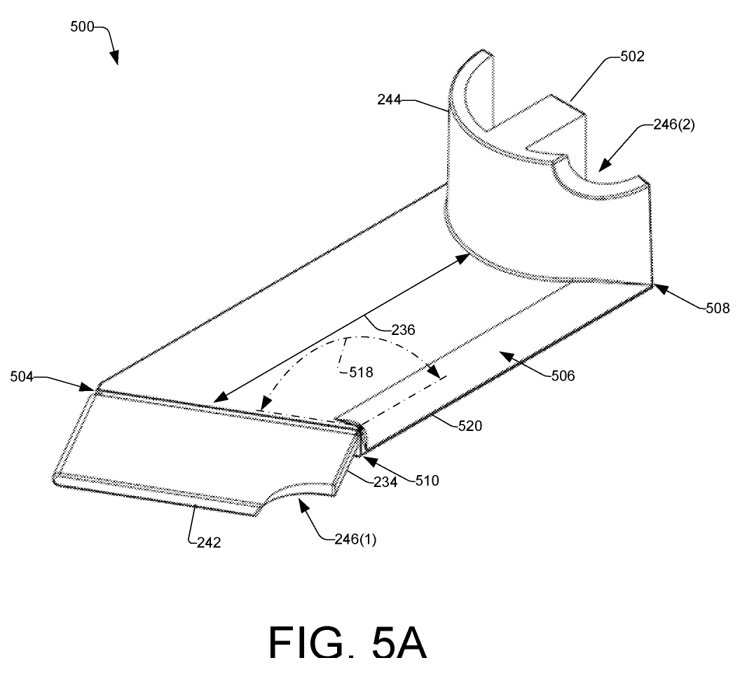

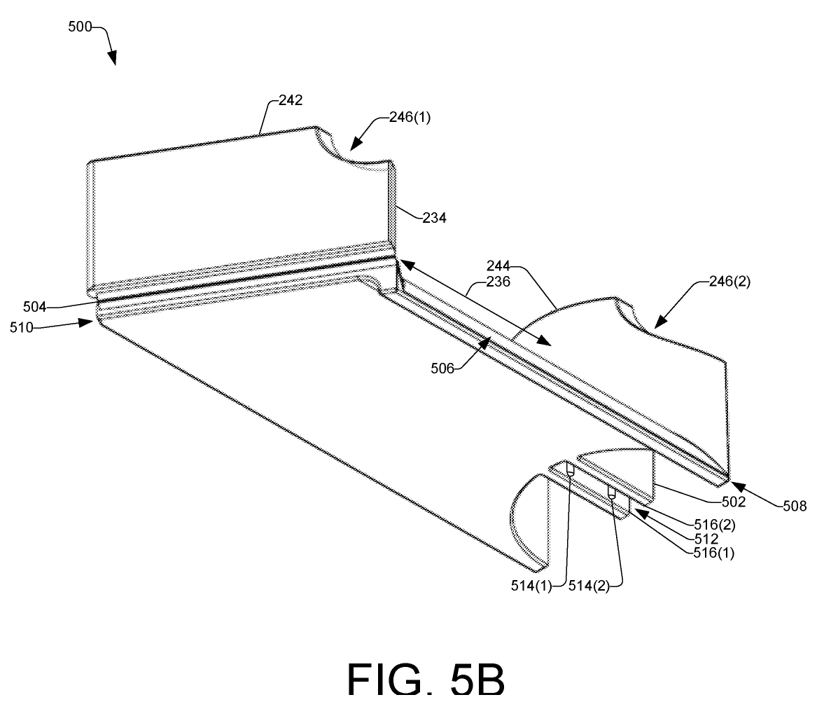

Inasmuch as FIGS. 5A and 5B depict different elements and features of the gates, while referring to the same elements and features of the gates 108 and/or the one or more gates 204(1) and 204(2), the following discussion of specific features may refer interchangeably to either or each of FIGS. 1, 2A, 2B, and 2C, except where explicitly indicated. In particular, FIGS. 5A and 5B illustrate an embodiment of a gate 500, including an attachment mechanism 502, a living hinge 504, and a beveled surface 506.

FIG. 5A illustrates a top perspective view of the gate 500 with the flap 234 in the open position. FIG. 5B illustrates a bottom perspective view of the gate 500 with the flap 234 in the closed position. FIGS. 5A and 5B illustrate the channel 236 having a first end 508 opposite a second end 510 and the attachment mechanism 502 disposed at the first end 508 of the channel 236. The attachment mechanism 502 may be disposed at the first end 508 of the channel 236 for attaching the gate 500 to the first sidewall 212 or the second sidewall 214. For example, as shown in FIG. 5B, the attachment mechanism 502 may include a slot 512 for fixing the gate 500 to the first sidewall 212 or the second sidewall 214 via an interference fit between the slot 512 and a cooperating notch arranged in the first sidewall 212 or the second sidewall 214. The gate 500 may be attached to the first sidewall 212 or the second sidewall 214 via the slot 512, matching up with the notch arranged in the first sidewall 212 or the second sidewall 214 of the chassis 206 to prevent forward and backward movement of the gate 500. FIG. 5B illustrates that the slot 512 may include one or more crush ribs 514(1) and 514(N) arranged on both inside surfaces 516(1) and 516(2) of the slot 512. The slot 512 may provide for a tight interference fit on the first sidewall 212 or the second sidewall 214 of the chassis 206. Moreover, when the lid 240 is installed on top of the chassis 206, the lid 240 may fully capture the gates and prevent up/down movement of the gates.

FIGS. 5A and 5B illustrate the flap 234 attached to the second end 510 of the channel 236. The flap 234 may be attached to the second end 510 of the channel 236 via the living hinge 504 such that the flap 234 may be displaceable between the open position and the closed position. FIG. 5A illustrates that the flap 234 may be attached to the second end 510 of the channel 236 at an obtuse angle 518. The obtuse angle 518 of the flap 234 may provide for an in-line path for the optical fiber to enter the chassis 206. For example, the obtuse angle 518 of the flap 234 may provide for a substantially nearly parallel path for the optical fiber to enter the rear of the chassis storage area from the exterior. For example, when the flap 234 is in the closed position, the obtuse angle 518 of the flap 234 may cause the fiber optic cable received by the channel 236 to enter the channel 236 rectilinearly to limit bending of the fiber optic cable received by the channel 236. The in-line, substantially nearly parallel, path along the angled flap 234 may provide for minimizing and/or limiting any sharp bends of the optical fiber when the shelf 218 is displaced between the closed position and/or the open position. Moreover, as discussed above concerning FIG. 2A, the angle 518 of the flap 234 may provide the gap 248 between the front panel 250 of the shelf 218 and the flap 234 of the gate 500 for a fingertip to pull the shelf 218 and displace the shelf 218 from the stowed position to the open position. FIGS. 5A and 5B illustrate the beveled surface 506 may extend along an edge 520 disposed between the first end 508 of the channel 236 and the second end 510 of the channel 236. The beveled surface may provide for protecting the fiber optic cable received through channel 236.

The gate 500 may include a monolithic structure formed of a single unit of material. The single unit of material may be Polypropylene (PP) or Polyethylene (PE). While FIGS. 5A and 5B illustrate the gate 500 as including a right-sided gate, the gate 500 may be a left-sided gate, where the left-sided gate is substantially a mirror image of the right-sided gate. For example, and as discussed above, the right-sided gate may be gate 204(1) fixed to the first sidewall 212 of the chassis 206 while the left-sided gate may be gate 204(2) fixed to the second sidewall 214 of the chassis 206.

### CONCLUSION

Although the disclosed subject matter has been described in language specific to structural features and/or methodological acts, it is to be understood that the disclosed subject matter is not necessarily limited to the specific features or acts described. Rather, the specific features and acts are disclosed as illustrative forms of implementing the disclosed subject matter. For example, while embodiments are described having certain shapes, sizes, and configurations, these shapes, sizes, and configurations are merely illustrative.

What is claimed is:

1. A data communication apparatus comprising:
a chassis having a front access side, a rear side opposite the front access side, and a first side opposite a second side, the chassis including:
a rear wall disposed at the rear side;
a first sidewall extending from the rear wall at the rear side toward the front access side proximate to the first side; and
a second sidewall extending from the rear wall at the rear side toward the front access side proximate to the second side; and
a gate fixed to the first sidewall or the second sidewall, the gate including:
a channel having a first end opposite a second end, the channel configured to receive fiber optic cable therethrough;
an attachment mechanism disposed at the first end of the channel for attaching the gate to the first sidewall or the second sidewall; and
a flap attached to the second end of the channel, the flap being attached to the second end of the channel via a living hinge such that the flap is displaceable between an open position and a closed position,
wherein when in the closed position a free end of the flap is positioned to enclose the channel, and
wherein when in the open position the free end of the flap is positioned to permit access to an interior of the channel.

2. The data communication apparatus of claim 1, wherein the gate further includes a bumper disposed around the attachment mechanism for protecting the fiber optic cable received through the channel.

3. The data communication apparatus of claim 2, wherein the gate further includes a first notch disposed in a top portion of the flap and a second notch disposed in a top portion of the bumper, the first notch and second notch for allowing a tool access to mount the chassis with hardware.

4. The data communication apparatus of claim 1, wherein the channel includes:
an edge disposed between the first end of the channel and the second end of the channel; and
a beveled surface disposed along the edge between the first end of the channel and the second end of the channel, the beveled surface for protecting the fiber optic cable received through the channel.

5. The data communication apparatus of claim 1, wherein the gate further includes a monolithic structure formed of a single unit of material.

6. The data communication apparatus of claim 5, wherein the single unit of material includes Polypropylene (PP) or Polyethylene (PE).

7. The data communication apparatus of claim 1, wherein the attachment mechanism includes a slot, the slot for fixing the gate to the first sidewall or the second sidewall via an interference fit between the slot and a cooperating notch arranged in the first sidewall or the second sidewall.

8. The data communication apparatus of claim 7, further comprising:
one or more crush ribs arranged on inside surfaces of the slot.

9. The data communication apparatus of claim 1, wherein the flap is attached to the second end of the channel at an obtuse angle,
wherein when the flap is in the closed position the obtuse angle of the flap causes the fiber optic cable received by the channel to enter the channel rectilinearly to limit bending of the fiber optic cable received by the channel.

10. A gate comprising:
a channel having a first end opposite a second end, the channel configured to receive fiber optic cable therethrough;
an attachment mechanism disposed at the first end of the channel for attaching the gate to a sidewall of a chassis; and
a flap attached to the second end of the channel, the flap being attached to the second end of the channel via a living hinge such that the flap is displaceable between an open position and a closed position,
wherein when in the closed position a free end of the flap is positioned to enclose the channel, and
wherein when in the open position the free end of the flap is positioned to permit access to an interior of the channel.

11. The gate of claim 10, further comprising a bumper disposed around the attachment mechanism for protecting the fiber optic cable received through the channel.

12. The gate of claim 11, further comprising:
a first notch disposed in a top portion of the flap; and
a second notch disposed in a top portion of the bumper,
wherein the first notch and second notch allow a tool access to mount the chassis with hardware.

13. The gate of claim 10, wherein the channel includes:
an edge disposed between the first end of the channel and the second end of the channel; and
a beveled surface disposed along the edge between the first end of the channel and the second end of the channel, the beveled surface for protecting the fiber optic cable received through the channel.

14. The gate of claim 10, wherein the channel, the attachment mechanism, and the flap are a monolithic structure formed of a single unit of material.

15. The gate of claim 10, wherein the flap is attached to the second end of the channel at an obtuse angle,
wherein when the flap in the closed position the obtuse angle of the flap causes the fiber optic cable received by the channel to enter the channel rectilinearly and limit bending of the fiber optic cable received by the channel.

16. The gate of claim 10, wherein the attachment mechanism includes a slot for interference fitting the gate to the sidewall of the chassis.

17. A gate comprising:
a channel having a first end opposite a second end, the channel configured to receive fiber optic cable therethrough;
an attachment mechanism disposed at the first end of the channel for attaching the gate to a portion of a chassis; and
a flap attached to the second end of the channel, the flap being attached to the second end of the channel via a living hinge such that the flap is displaceable between an open position and a closed position,
wherein when in the closed position a free end of the flap is positioned to enclose the channel, and
wherein when in the open position the free end of the flap is positioned to permit access to an interior of the channel.

19. The gate of claim 17, wherein the channel includes:
an edge disposed between the first end of the channel and the second end of the channel; and
a beveled surface disposed along the edge between the first end of the channel and the second end of the channel, the beveled surface for protecting the fiber optic cable received through the channel.

20. The gate of claim 17, wherein the channel, the attachment mechanism, and the flap are a monolithic structure formed of a single unit of material.

21. The gate of claim 17, wherein the attachment mechanism includes a slot for interference fitting the gate to the portion of the chassis.

22. The gate of claim 17, further comprising a bumper disposed around the attachment mechanism for protecting the fiber optic cable received through the channel.

23. The gate of claim 22, wherein the flap is attached to the second end of the channel at an obtuse angle,
wherein when the flap in the closed position the obtuse angle of the flap causes the fiber optic cable received by the channel to enter the channel rectilinearly and limit bending of the fiber optic cable received by the channel.

24. The gate of claim 23, further comprising:
a first notch disposed in a top portion of the flap; and
a second notch disposed in a top portion of the bumper,
wherein the first notch and second notch allow a tool access to mount the chassis with hardware.
